(19) United States
(12) Patent Application Publication
(10) Pub. No.: US 2021/0074802 A1
(43) Pub. Date: Mar. 11, 2021

(54) DISPLAY PANEL AND DISPLAY DEVICE

(71) Applicant: Zhiwei ZHOU, Wuhan, Hubei (CN)

(72) Inventor: Zhiwei ZHOU, Wuhan, Hubei (CN)

(21) Appl. No.: 16/769,053

(22) PCT Filed: Dec. 12, 2009
(86) PCT No.: PCT/CN2019/124728

§ 371 Date: Jun. 2, 2020

(30) Foreign Application Priority Data
Sep. 2, 2019 (CN) 201910823792.5

(51) Int. Cl. H01L 27/32

(52) U.S. Cl. CPC H01L 27/3279

(57) ABSTRACT

The present application provides a display panel and a display device. In the present application, by changing a method in which a power supply voltage signal is introduced, and providing the power supply voltage signal at different positions at a same time to solve a problem of voltage drop of the display panel, a problem of uneven screen brightness is relieved.

### CROSS REFERENCE TO RELATED APPLICATION

The present application claims priority of a Chinese patent application filed with the National Intellectual Property Administration on Sep. 2, 2019, application No. 201910823792.5, titled “Display panel and display device”, which is incorporated by reference in the present application in its entirety.

### FIELD OF INVENTION

The present application relates to the field of display technology, and particularly relates to a display panel and a display device.

### BACKGROUND OF INVENTION

When an organic light-emitting diode (OLED) emits light, its driving current is related to its power supply voltage, and the driving current needs to be supplied by the power supply voltage VDD. Considering impedance exists in traces of the power supply voltage VDD, an actual VDD voltage obtained by a pixel unit is less than a VDD voltage provided by a power supply under an effect of resistance drop (IR drop). That is, VDDₚᵢₓₑₗ=VDD−I_{oled}*R_{VDD}. As shown in FIG. 1, compared to the lower end of the display panel, the upper end of the display panel is relatively farther away from the power supply voltage VDD, and the resistance is relatively larger. Therefore, the power supply voltage VDD at this position drops more severely, which may cause the upper end of the display panel to be dark and the lower end to be bright, and seriously affect the brightness uniformity of the display panel.

How to effectively solve the problem of dark upper end and bright lower end of the display panel and improve the brightness uniformity of the display panel is an important issue in the display technology.

### Technical Problem

An objective of the present application is to provide a display panel and a display device, which can solve the problems in the prior art.

### SUMMARY OF INVENTION

To solve the above problems, the present application provides a display panel and a display device.

According to an aspect of the present application, the present application provides a display panel, including: a display area and a non-display area positioned at a periphery of the display area; a first trace disposed in the non-display area, the first trace forming a closed-loop, the first trace disposed around the display area, and the first trace being a source-drain trace; a plurality of second traces penetrating the display area along a longitudinal direction of the display panel, and the plurality of second traces each electrically connected to the first trace; and a driver chip electrically connected to the first trace, configured to generate a power terminal voltage signal of the display panel, and the power terminal voltage signal transmitted to the second traces through the first trace.

According to another aspect of the present application, the present application provides a display panel, including: a display area and a non-display area positioned at a periphery of the display area; a first trace disposed in the non-display area and the first trace forming a closed-loop; a plurality of second traces penetrating the display area along a longitudinal direction of the display panel, and the plurality of second traces each electrically connected to the first trace; and a driver chip electrically connected to the first trace, configured to generate a power terminal voltage signal of the display panel, and the power terminal voltage signal transmitted to the second traces through the first trace.

Further, the first trace is disposed around the display area.

Further, the first trace is a source-drain trace.

Further, the driver chip is disposed at one end of the non-display area along a longitudinal direction of the display panel.

Further, the display panel further includes at least one third trace, the at least one third trace runs through the display area along a lateral direction of the display panel, and the at least one third trace is electrically connected to the first trace and the second traces, respectively and is configured to receive the power terminal voltage signal transmitted by the first trace and generated from the driver chip, and transmit the power terminal voltage signal to the second traces.

Further, the third trace and the first trace are disposed on the same layer.

Further, when the number of the third trace is single, the third trace runs through the display area along a central axis of the display area.

Further, when the number of the third trace is plural, the third traces are disposed at the same interval from each other.

Further, the third trace is in communication with the second traces through a via-hole structure.

According to yet another aspect of the present application, the present application provides a display device including the display panel as described above.

### BENEFICIAL EFFECT

The present application discloses a display panel and a display device. In the present application, by changing a method in which a power supply voltage signal is introduced, and providing the power supply voltage signal at different positions at a same time to solve a problem of voltage drop of the display panel, a problem of uneven brightness is relieved.

### DESCRIPTION OF DRAWINGS

FIG. 1 is a schematic structural diagram of a display panel provided in the prior art.

FIG. 2 is a schematic structural diagram of a display panel according to an embodiment of the present application.

FIG. 3 is a schematic structural diagram of a via-hole provided in an embodiment of the present application.

FIG. 4 is a schematic structural diagram of a trace changing process according to an embodiment of the present application.

FIG. 5 is a schematic structural diagram of another display panel according to an embodiment of the present application.

FIG. 6 is a schematic flowchart of another display panel according to an embodiment of the present application.

FIG. 7 is a schematic structural diagram of a display device according to an embodiment of the present application.

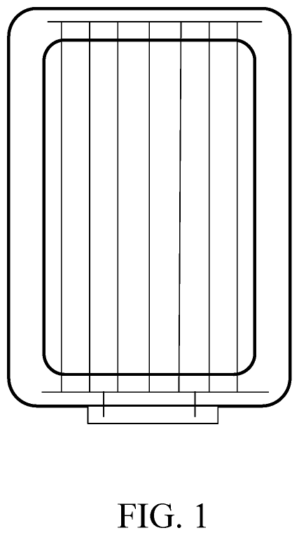

### DETAILED DESCRIPTION OF PREFERRED EMBODIMENTS

The technical solutions in the embodiments of the present application will be clearly and completely described below with reference to the drawings in the embodiments of the present application. Obviously, the described embodiments are only a part of the embodiments of the present application, but not all the embodiments. Based on the embodiments in the present application, all other embodiments obtained by those skilled in the art without creative work fall into the protection scope of the present application.

The terms “first”, “second”, “third” (if present) and the like in the specification and claims of the present application and the above-mentioned drawings are used to distinguish similar objects and are not used to describe a specific order or sequence. It should be understood that the objects are interchangeable under appropriate circumstances. In addition, the terms “including” and “having” and any of their variations are intended to encompass a non-exclusive inclusion.

In the description of the present application, the drawings and the embodiments used to describe the principles disclosed in the present application are for illustration purposes only and should not be construed as limiting the scope of the present disclosure. Those skilled in the art will understand that the principles of the present application may be implemented in any properly arranged system. Exemplary embodiments will be explained in detail, and examples of the embodiments are shown in the drawings. In addition, a terminal according to an exemplary embodiment will be described in detail with reference to the accompanying drawings. The same reference numerals in the drawings refer to the same elements.

The terms used in the specification of the present application are only used to describe specific embodiments and are not intended to show the concepts of the present application. Unless the context clearly indicates a different meaning, expressions used in the singular encompass the expression in the plural. In the present specification, it should be understood that terms such as “including”, “having” and “containing” are intended to indicate the possibility of the features, numbers, steps, actions, or combinations thereof disclosed in the specification, and it is not intended to exclude the possibility that one or more other features, numbers, steps, actions, or a combination thereof may be present or may be added. The same reference numerals in the drawings refer to the same parts.

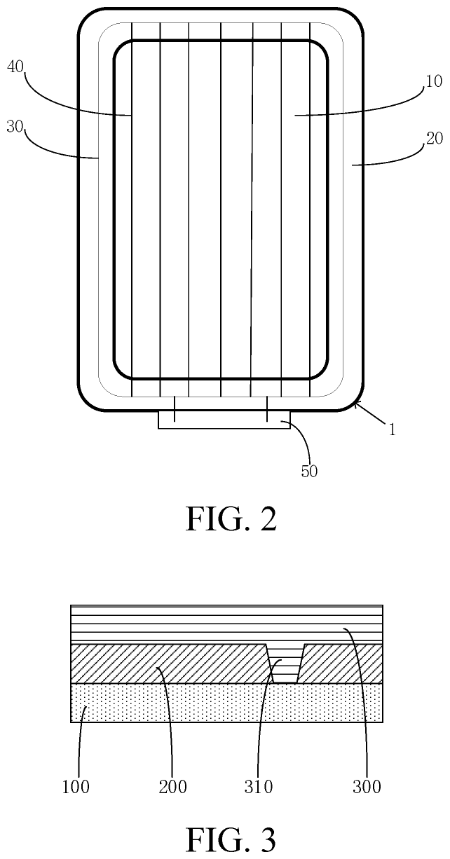

As shown in FIG. 2, an embodiment of the present application provides a display panel 1, including a display area 10, a non-display area 20, a first trace 30, a second trace 40, and a driver chip 50.

Specifically, the non-display area 20 is positioned at a periphery of the display area 10. The first trace 30 is disposed on the non-display area 20, and in the present embodiment, the first trace 30 surrounds the display area 10 to form a closed-loop, so that the first trace 30 simultaneously provides a same VDD signal at both ends of the display panel 1. Therefore, a voltage-drop caused by a single VDD signal provided from the driver chip 50 can be reduced to relieve the problem of uneven brightness of the display panel 1. The first trace 30 is a source-drain (SD) trace.

The plurality of second traces 40 run through the display area 10 along the longitudinal direction of the display panel 1, and the plurality of second traces 40 are electrically connected to the first traces 30. The second traces 40 are used to provide voltage to a thin-film transistor.

The driver chip 50 is disposed at one end of the non-display area 20 along the longitudinal direction of the display panel 1 and is electrically connected to the first trace 30. The driver chip 50 is used for generating the VDD signal of the display panel 1 and the VDD signal is provided to the second traces 40 through the first trace 30.

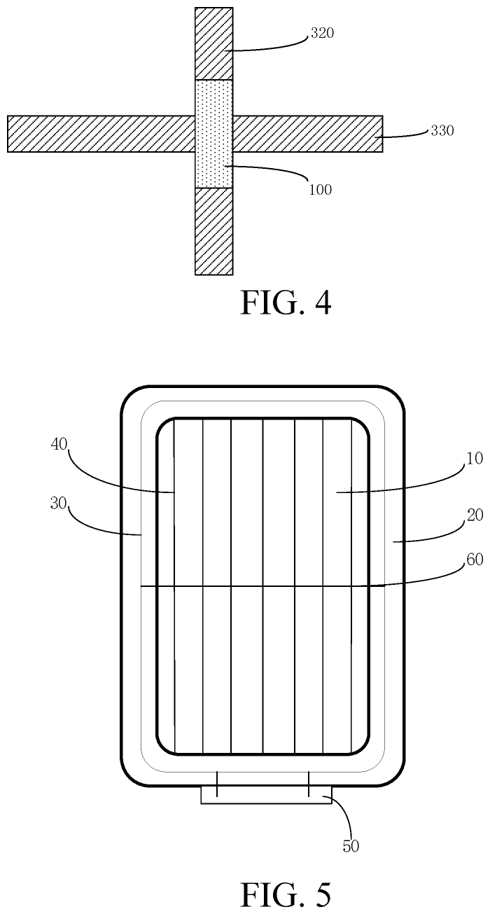

As shown in FIG. 3 and FIG. 4, due to a design of the first trace 30, there are more longitudinal SD traces 320 arranged along the longitudinal direction of the display panel 1 than that in the prior art. This may cause a short circuit with the lateral SD trace 330 that is originally arranged along the lateral direction of the display panel 1 on the same layer. Therefore, it is necessary to use a method of contact (CNT) via-hole 310 to perform trace conversion on an insulation layer 200 at the intersection, so that the longitudinal SD trace 320 positioned at the intersection is replaced with a metal trace 100 of a different layer to prevent a risk of short circuit.

As shown in FIG. 5, an embodiment of the present application provides another display panel 1, which includes a display area 10, a non-display area 20, a first trace 30, a second trace 40, a driver chip 50, and a third trace 60.

Specifically, the non-display area 20 is positioned at a periphery of the display area 10.

The first trace 30 is disposed on the non-display area 20, and in the present embodiment, the first trace 30 surrounds the display area 10 to form a closed-loop. The first trace 30 is a source-drain (SD) trace.

The plurality of second traces 40 run through the display area 10 along the longitudinal direction of the display panel, and the plurality of second traces 40 are electrically connected to the third trace 60. The second traces 40 are used to provide a voltage to the thin-film transistor.

The driver chip 50 is disposed at one end of the non-display area 20 along the longitudinal direction of the display panel 1 and is electrically connected to the first trace 30. The driver chip 50 is used for generating a VDD signal of the display panel 1.

The third trace 60 runs through the display area 10 along the central axis of the display panel 1 in the lateral direction. The third trace 60 is electrically connected to the first trace 30 and the second traces 40, respectively. The third trace 60 is configured to receive the VDD signal transmitted from the first trace 30 and generated by the driver chip 50, and transmit the VDD signal to the second traces 40. The third trace 60 is disposed on the same layer as the first trace 30, and the third trace 60 is in communication with the second traces 40 through a via-hole structure.

The display panel 1 simultaneously provides the VDD signal to both ends of the display panel 1 from the central position through the third trace 60, which further decreases the number of thin-film transistors in the VDD signal path, reduces voltage drop, and relieves the problem of uneven brightness of the display panel 1.

As shown in FIG. 3 and FIG. 4, due to the design of the first trace 30, there are more longitudinal SD traces 320 arranged along the longitudinal direction of the display panel 1 than that in the prior art. This may cause a short circuit with the lateral SD trace 330 that is originally arranged along the lateral direction of the display panel 1 on the same layer. Therefore, it is necessary to use a method of contact (CNT) via-hole 310 to perform trace conversion on the insulation layer 200 at the intersection, so that the longitudinal SD trace 320 positioned at the intersection is replaced with a metal trace 100 of a different layer to prevent a risk of short circuit.

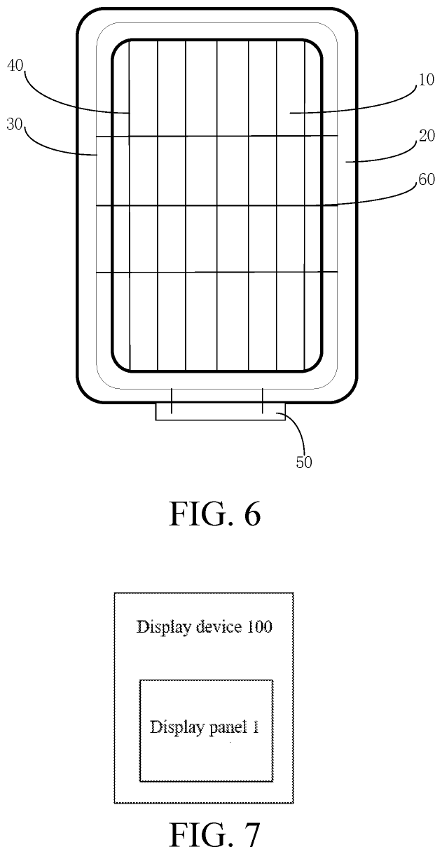

As shown in FIG. 6, an embodiment of the present application provides another display panel 1, including a display area 10, a non-display area 20, a first trace 30, a second trace 40, a driver chip 50, and a third trace 60. Specifically, the non-display area 20 is positioned at a periphery of the display area 10.

The first trace 30 is disposed on the non-display area 20. In the present embodiment, the first trace 30 surrounds the display area 10 to form a closed-loop. The first trace 30 is a source-drain (SD) trace.

The plurality of second traces 40 run through the display area 10 along the longitudinal direction of the display panel 1, and the plurality of second traces 40 are electrically connected to the third trace 60. The second traces 40 are used to provide a voltage to the thin-film transistor.

The driver chip 50 is disposed at one end of the non-display area 20 along the longitudinal direction of the display panel 1 and is electrically connected to the first trace 30. The driver chip 50 is used for generating a VDD signal of the display panel 1.

The third trace 60 runs through the display area 10 along the lateral direction of the display panel 1. In the present embodiment, there are three third traces 60, and the third traces 60 are arranged at equal intervals from each other. The third trace 60 is electrically connected to the first trace 30 and the second traces 40, respectively, and is configured to receive the VDD signal transmitted from the first trace 30 and generated by the driver chip 50 and transmit the VDD signal to the second traces 40. The third trace 60 is disposed on the same layer as the first trace 30, and the third trace 60 is in communication with the second traces 40 through a via-hole structure.

The display panel 1 simultaneously provides the VDD signal to both ends of the display panel 1 from three positions through the third trace 60, which further decreases the number of thin-film transistors in the VDD signal path, reduces voltage drop, and relieves the problem of uneven brightness of the display panel 1.

As shown in FIG. 3 and FIG. 4, due to the design of the first trace 30, there are more longitudinal SD traces 320 arranged along the longitudinal direction of the display panel 1 than that in the prior art. This may cause a short circuit with the lateral SD trace 330 that is originally arranged along the lateral direction of the display panel 1 on the same layer. Therefore, it is necessary to use a method of contact (CNT) via-hole 310 to perform trace conversion on the insulation layer 200 at the intersection, so that the longitudinal SD trace 320 positioned at the intersection is replaced with a metal trace 100 of a different layer to prevent a risk of short circuit. These three third traces 60 will reduce the space for the pixels to be set. Therefore, corresponding modifications need to be made to the relevant traces in the display area 10.

As shown in FIG. 7, an embodiment of the present application further provides a display device 100 including the display panel 1 as described above, to improve the problem of uneven brightness of the screen caused by the problem of voltage drop. In the present application, by changing the method in which the power supply voltage signal is introduced, and providing the power supply voltage signal at different positions at the same time to solve the voltage drop problem of the display panel, the problem of uneven brightness is relieved.

The display panel and display device provided in the embodiments of the present application have been described in detail above. Specific examples are used in this article to explain the principle and implementation of the present application. The description of the above embodiments is only used to help understand the method of the present application and its core ideas. In addition, for those skilled in the art, according to the idea of the present application, there will be changes in the specific implementation and the scope of application. As described above, the content of the description should not be understood as a limitation on the present application.

### INDUSTRIAL APPLICABILITY

The subject matter of the present application can be manufactured and used in industry, and thus has industrial applicability.

What is claimed is:

1. A display panel, comprising:
a display area and a non-display area positioned at a periphery of the display area;
a first trace disposed in the non-display area, wherein the first trace forms a closed-loop, the first trace is disposed around the display area, and the first trace is a source-drain trace;
a plurality of second traces running through the display area along a longitudinal direction of the display panel, wherein the plurality of second traces are each electrically connected to the first trace; and
a driver chip electrically connected to the first trace, configured to generate a power terminal voltage signal of the display panel, wherein the power terminal voltage signal is transmitted to the second traces through the first trace.

2. A display panel, comprising:
a display area and a non-display area positioned at a periphery of the display area;
a first trace disposed in the non-display area, wherein the first trace forms a closed-loop;
a plurality of second traces running through the display area along a longitudinal direction of the display panel, wherein the plurality of second traces are each electrically connected to the first trace; and
a driver chip electrically connected to the first trace, configured to generate a power terminal voltage signal of the display panel, wherein the power terminal voltage signal is transmitted to the second traces through the first trace.

3. The display panel according to claim 2, wherein the first trace is disposed around the display area.

4. The display panel according to claim 2, wherein the first trace is a source-drain trace.

5. The display panel according to claim 2, wherein the driver chip is disposed at one end of the non-display area along the longitudinal direction of the display panel.

6. The display panel according to claim 2, wherein the display panel further comprises at least one third trace, the at least one third trace runs through the display area along a lateral direction of the display panel, and the at least one third trace is electrically connected to the first trace and the second traces, respectively, and is configured to receive the power terminal voltage signal transmitted by the first trace and generated from the driver chip, and transmit the power terminal voltage signal to the second traces.

7. The display panel according to claim 2, wherein at least one third trace and the first trace are disposed on a same layer.

8. The display panel according to claim 6, wherein when a number of the at least one third trace is single, the third trace runs through the display area along a central axis of the display area.

9. The display panel according to claim 6, wherein when a number of the at least one third trace is plural, the third traces are disposed at a same interval from each other.

10. The display panel according to claim 8, wherein the at least one third trace is in communication with the second traces through a via-hole structure.

11. A display device, comprising the display panel according to claim 1.
